(19) United States
(12) Patent Application Publication
(10) Pub. No.: US 2025/0022957 A1
(43) Pub. Date: Jan. 16, 2025

(54) EPITAXIAL STRUCTURES FOR SEMICONDUCTOR DEVICES AND MANUFACTURING METHODS THEREOF

(71) Applicant: Taiwan Semiconductor Manufacturing Company, Ltd., Hsin-Chu (TW)

(72) Inventors: Che-Yu Lin, Hsinchu City (TW); Chien-Chia Cheng, Hsinchu City (TW); Chih-Chiang Chang, Hsinchu County (TW); Chien-I Kuo, Zhubei City (TW); Ming-Hua Yu, Hsinchu City (TW); Chii-Horng Li, Hsinchu County (TW); Syun-Ming Jang, Hsin-Chu (TW); Wei-Jen Lo, Hsinchu City (TW)

(21) Appl. No.: 18/492,258

(22) Filed: Oct. 23, 2023

Related U.S. Application Data
(60) Provisional application No. 63/513,600, filed on Jul. 14, 2023.

(51) Int. Cl. H01L 29/78; H01L 29/66; H01L 29/775; H01L 29/786

(52) U.S. Cl. CPC H01L 29/7848; H01L 29/66439; H01L 29/66742; H01L 29/775; H01L 29/78696; H01L 29/42392

(57) ABSTRACT

The present disclosure provides a semiconductor device and a method of forming the same. A method according one embodiment of the present disclosure include forming a stack over a substrate, forming a fin-shape structure from patterning the stack and the substrate, recessing the fin-shape structure to form a source/drain trench, depositing a dielectric film in the source/drain trench with a top surface below a top surface of the substrate in the fin-shape structure, and forming an epitaxial feature over the dielectric film. A bottom surface of the epitaxial feature is below the top surface of the substrate in the fin-shape structure.

### PRIORITY DATA

This application claims priority to U.S. Provisional Patent Application No. 63/513,600, filed on Jul. 14, 2023, entitled “Epitaxial Structures For Semiconductor Devices And Manufacturing Methods Thereof”, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as IC technologies progress towards smaller nodes, multi-gate metal-oxide-semiconductor field effect transistor (multi-gate MOSFET, or multi-gate devices) have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and multi-bridge-channel (MBC) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor.

To improve performance of an MBC transistor, efforts are invested to develop epitaxial features that strain channels and provide reduced resistance. While conventional epitaxial features are generally adequate to their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor device, according to one or more aspects of the present disclosure.

FIGS. 2, 3, 4, 5, 6, 7, 8, 9, 10, 11, 12, 13, 14, 15, 16, 17, 18, 19, 20, 21, and 22 illustrate fragmentary cross-sectional views of a workpiece during a fabrication process according to the method of FIG. 1, according to one or more aspects of the present disclosure.

FIGS. 23A, 23B, 23C, 23D, 23E, and 23F illustrate fragmentary cross-sectional views of alternative embodiments of the workpiece, according to one or more aspects of the present disclosure.

FIGS. 24A, 24B, 24C, 24D, 24E, 24F, 24G, 24H, and 24I illustrate fragmentary cross-sectional views of alternative embodiments of a region that includes a source/drain feature of the workpiece, according to one or more aspects of the present disclosure.

FIGS. 25A, 25B, 25C, 25D, 25E, 25F, 25G, 25H, 25I, 25J, and 25K illustrate fragmentary cross-sectional views of alternative embodiments of a region that includes a source/drain feature of the workpiece, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure is generally related to multi-gate transistors and fabrication methods, and more particularly to multilayer epitaxial features of MBC transistors. Channel regions of an MBC transistor may be disposed in nanowire channel members, bar-shaped channel members, nanosheet channel members, nanostructure channel members, column-shaped channel members, post-shaped channel members, and/or other suitable channel configurations. Depending on the shapes of the channel members, MBC transistors may also be referred to as nanowire transistors or nanosheet transistors. Despite of the shapes, each of the channel members of an MBC transistor extend between and are coupled to two source/drain features. Ideal source/drain features of an MBC transistor introduce strain on the channel members and provide low resistance. During the formation of the MBC transistor, inserting a dielectric film that is leveled with the bottom surface of an epitaxial stack that comprises the channel members may help isolating the source/drain features from the substrate and thus suppress leakage current into the substrate. Although such a dielectric film is helpful to boost AC performance, it may deteriorate DC performance in p-type FETs with an increased resistance. The deterioration of DC performance in p-type FETs may be due to a reduced volume of the source/drain features which is confined by the position of the dielectric film. Further, the deterioration of DC performance in p-type FETs may also be due to a loss of compressive strain with the reduced volume of the source/drain features.

The present disclosure provides embodiments of a semiconductor device where its dielectric film underneath source/drain features in p-type FETs is positioned below the top surface of the substrate on which the channel members are suspended. The relatively low position of the dielectric film allows the source/drain features extend into the substrate, which expands the volume of the source/drain features and safeguards a satisfying level of compressive strain with an enlarged volume of the source/drain features. Further, a base epitaxial layer may optionally be formed between the substrate and the dielectric film. The base epitaxial layer may be undoped to increase its resistance, which further improves the suppression of leakage current from the source/drain features into the substrate.

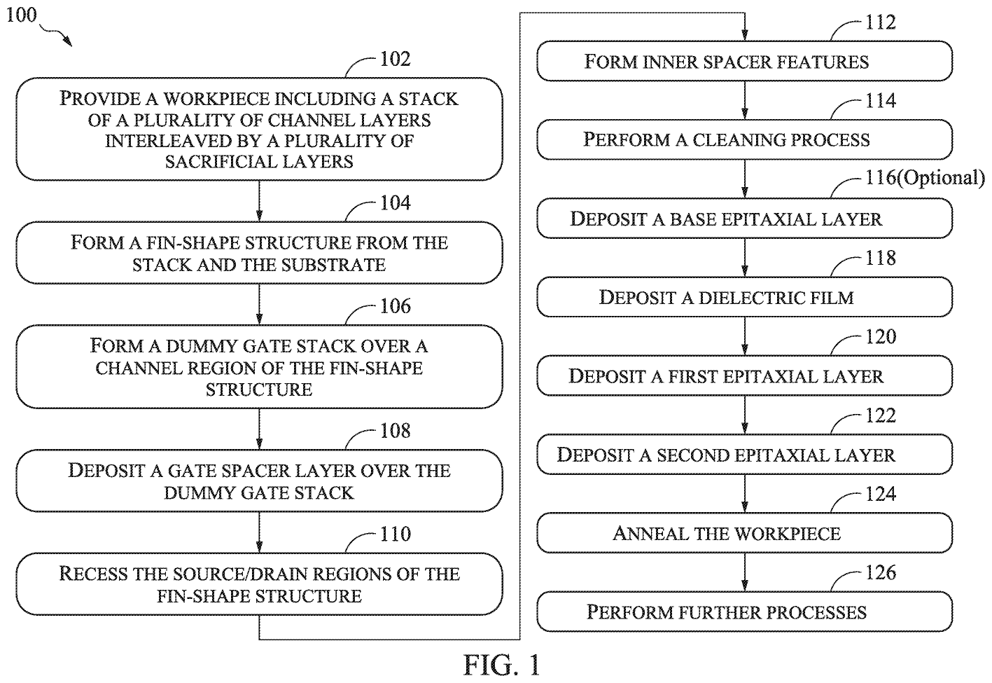

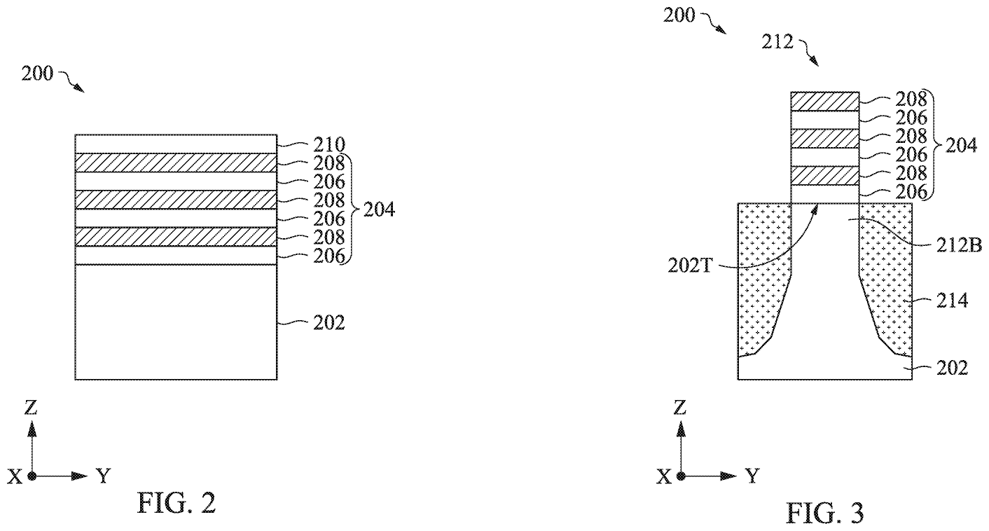

The various aspects of the present disclosure will now be described in more detail with reference to the figures. In that regard, FIG. 1 is a flowchart illustrating a method 100 of forming a semiconductor device from a workpiece according to embodiments of the present disclosure. Method 100 is merely an example and is not intended to limit the present disclosure to what is explicitly illustrated in method 100. Additional steps can be provided before, during and after method 100, and some steps described can be replaced, eliminated, or moved around for additional embodiments of the method. Not all steps are described herein in detail for reasons of simplicity. Method 100 is described below in conjunction with FIGS. 2-22, 23A-23F. 24A-24I, and 25A-25K, which are fragmentary cross-sectional views of workpiece 200 at different stages of fabrication according to embodiments of the method 100 in FIG. 1. Because the workpiece 200 will be fabricated into a semiconductor device, the workpiece 200 may be referred to herein as a semiconductor device 200 as the context requires. For avoidance, the X, Y and Z directions in FIGS. 2-22, 23A-23F, 24A-24I, and 25A-25K are perpendicular to one another. Throughout the present disclosure, like reference numerals denote like features, unless otherwise excepted.

Referring to FIGS. 1 and 2, method 100 includes a block 102 where a stack 204 of alternating semiconductor layers is formed over the workpiece 200. As shown in FIG. 2, the workpiece 200 includes a substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P) or arsenide (As). In embodiments where the semiconductor device is n-type, a p-type doping profile (i.e., a p-type well or p-well) may be formed on the substrate 202. In some implementations, the n-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 includes sacrificial layers 206 of a first semiconductor composition interleaved by channel layers 208 of a second semiconductor composition. The first and second semiconductor composition may be different. In some embodiments, the sacrificial layers 206 include silicon germanium (SiGe) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channels members for the semiconductor device 200. In some embodiments, the number of channel layers 208 is between 1 and 20.

In some embodiments, all sacrificial layers 206 may have a substantially uniform first thickness between about 3 nm and about 10 nm and all of the channel layers 208 may have a substantially uniform second thickness between about 3 nm and about 15 nm. The first thickness and the second thickness may be the same or different. As described in more detail below, the channel layers 208 or parts thereof may serve as channel member(s) for a subsequently-formed multi-gate device and the thickness of each of the channel layers 208 is chosen based on device performance considerations. The sacrificial layers 206 in channel regions(s) may eventually be removed and serve to define a vertical distance between adjacent channel region(s) for a subsequently-formed multi-gate device and the thickness of each of the sacrificial layers 206 is chosen based on device performance considerations.

The layers in the stack 204 may be deposited using a molecular beam epitaxy (MBE) process, a vapor phase deposition (VPE) process, and/or other suitable epitaxial growth processes. Therefore, the stack 204 is also referred to as the epitaxial stack 204. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 cm⁻³ to about 1×10¹⁷ cm⁻³), where for example, no intentional doping is performed during the epitaxial growth processes for the stack 204. In some implementations, the top surface of the substrate 202 is in a (100) crystalline plane, and accordingly each layer of the stack 204 has a (100) top surface. In some alternative implementations, the top surface of the substrate is in a (110) crystalline plane, and accordingly each layer of the stack 204 has a (110) top surface.

Referring to FIGS. 1, 2, and 3, method 100 includes a block 104 where a fin-shape structure 212 is formed from patterning the stack 204 and the substrate 202. To pattern the stack 204, a hard mask layer 210 (shown in FIG. 2) may be deposited over the stack 204 to form an etch mask. The hard mask layer 210 may be a single layer or a multi-layer. For example, the hard mask layer 210 may include a pad oxide layer and a pad nitride layer over the pad oxide layer. The fin-shape structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending through the stack 204 and a portion of the substrate 202. The trenches define the fin-shape structures 212. In some implementations, double-patterning or multi-patterning processes may be used to define fin-shape structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shape structure 212 by etching the stack 204 and a top portion of the substrate 202. The patterned top portion of the substrate 202 is also denoted as a fin-shape base 212B. A horizontal plane comprising an interface between the stack 204 and the fin-shape base 212B is denoted as the plane 202T, which marks a position of the bottom surface of the stack 204 and/or the top surface of the fin-shape base 212B. The fin-shape base 212B may still be considered as a top part of the substrate 202 as the context requires. Therefore, the plane 202T may also be considered as marking a position of the top surface of the substrate 202. As shown in FIG. 3, the fin-shape structure 212, which includes the patterned stack 204 and the fin-shape base 212B, extends vertically along the Z direction and lengthwise along the X direction. In some instances, the fin-shape structure 212 measures between about 6 nm and about 80 nm wide along the Y direction, and a distance between opposing sidewalls of two adjacent fin-shape structures 212 measures between about 6 nm and about 115 nm along the Y direction.

An isolation feature 214 is formed adjacent the fin-shape structure 212. In some embodiments, the isolation feature 214 may be formed in the trenches to isolate the fin-shape structures 212 from a neighboring active region. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214. The fin-shape structure 212 rises above the STI feature 214 after the recessing. The recessed top surface of the STI feature 214 may be leveled with the plane 202T or below the plane 202T.

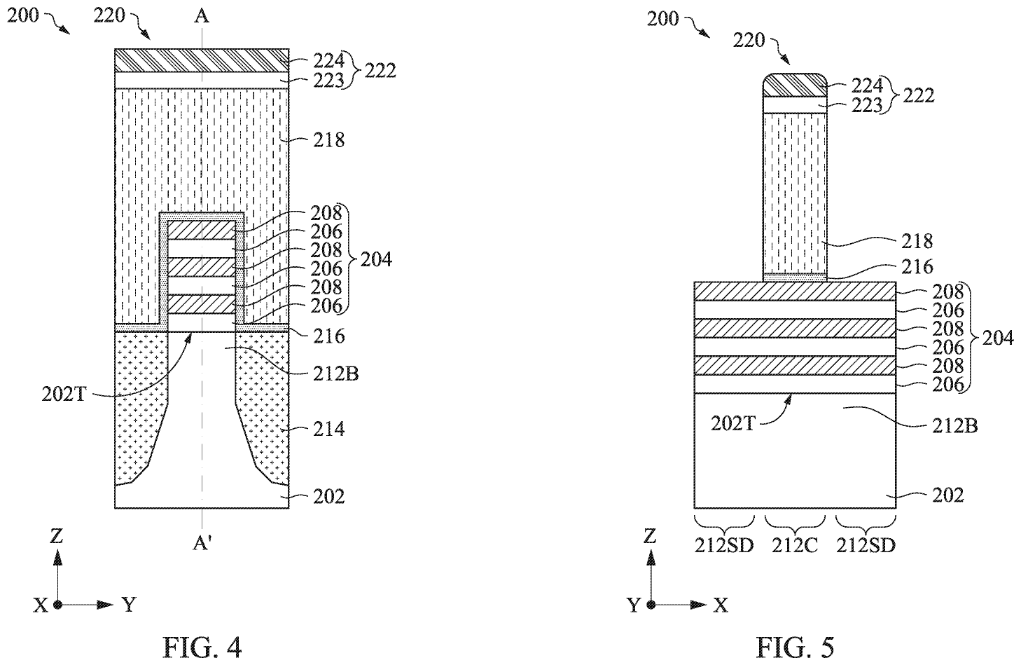

Referring to FIGS. 1, 4, and 5, method 100 includes a block 106 where a dummy gate stack 220 is formed over a channel region 212C of the fin-shape structure 212. FIG. 5 is a cross-sectional view cut through A-A′ line in FIG. 4. In some embodiments, a gate replacement process (or gate-last process) is adopted where the dummy gate stack 220 (shown in FIGS. 4 and 5) serves as a placeholder to undergo various processes and is to be removed and replaced by the functional gate structure. Other processes and configuration are possible. In some embodiments illustrated in FIG. 5, the dummy gate stack 220 is formed over the fin-shape structure 212 and the fin-shape structure 212 may be divided into channel regions 212C underlying the dummy gate stacks 220 and source/drain regions 212SD that do not underlie the dummy gate stacks 220. The channel regions 212C are adjacent the source/drain regions 212SD. As shown in FIG. 5, the channel region 212C is disposed between two source/drain regions 212SD along the X direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the workpiece 200. In some embodiments, the dummy dielectric layer 216 may be formed on the fin-shape structure 212 using a chemical vapor deposition (CVD) process, an ALD process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, no dummy gate stack 220 is disposed over the source/drain region 212SD of the fin-shape structure 212.

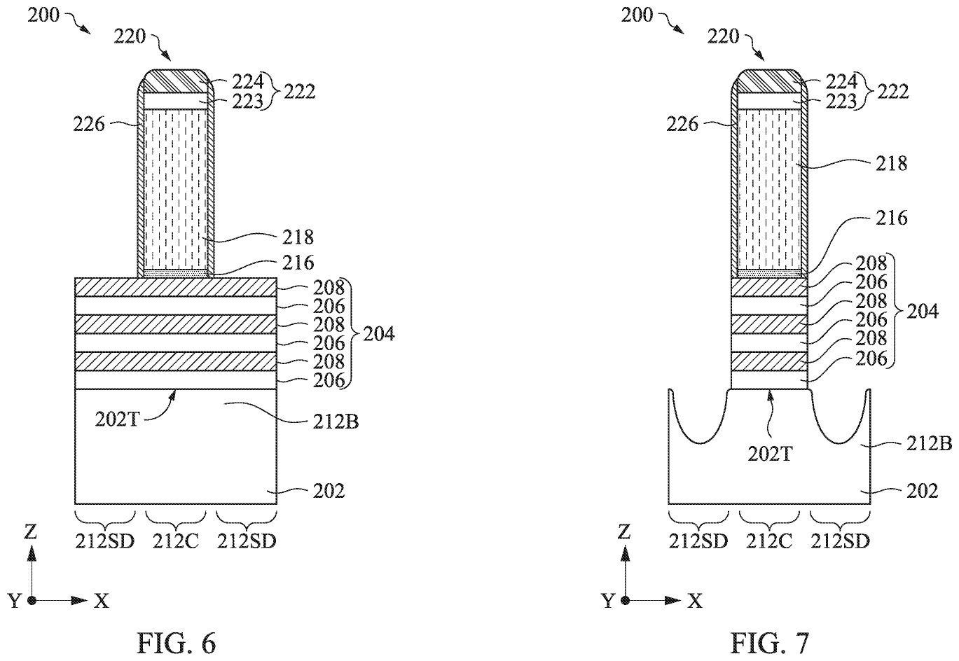

Referring to FIGS. 1 and 6, method 100 includes a block 108 where a gate spacer layer 226 is deposited over the dummy gate stack 220. In some embodiments, the gate spacer layer 226 is deposited conformally over the workpiece 200, including over top surface and sidewalls of the dummy gate stack 220. The term “conformally” may be used herein for case of description of a layer having substantially uniform thickness over various regions. The gate spacer layer 226 may be a single layer or a multi-layer. The at least one layer in the gate spacer layer 226 may include silicon carbonitride, silicon oxycarbide, silicon oxycarbonitride, or silicon nitride. The gate spacer layer 226 may be deposited over the dummy gate stack 220 using processes such as, a CVD process, a subatmospheric CVD (SACVD) process, an ALD process, or other suitable process. In one embodiment, the gate spacer layer 226 includes a first layer and a second layer disposed over the first layer. The first layer may include silicon oxynitride and the second layer may include silicon nitride. In some instances, the gate spacer layer 226 measures between about 3 nm and about 8 nm thick along the X direction.

Referring to FIGS. 1 and 7, method 100 includes a block 110 where a source/drain region 212SD of the fin-shape structure 212 is recessed to form a source/drain trench 228. In some embodiments, the source/drain regions 212SD that are not covered by the dummy gate stack 220 and the gate spacer layer 226 are etched by a dry etch or a suitable etching process to form the source/drain trenches 228. For example, the dry etch process may implement an oxygen-containing gas, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBR3), an iodine-containing gas, other suitable gases and/or plasmas, and/or combinations thereof. In some embodiments represented in FIG. 7, the source/drain regions 212SD of the fin-shape structure 212 are recessed to expose sidewalls of the sacrificial layers 206 and the channel layers 208. In some implementations, the source/drain trenches 228 extend below the stack 204 into the substrate 202 (below the plane 202T). FIG. 7 illustrates a cross-sectional view of the workpiece 200 viewed along the Y direction at the source/drain region 212SD. As shown in FIG. 7, the sacrificial layers 206 and channel layers 208 in the source/drain region 212SD are removed at block 110, exposing the substrate 202.

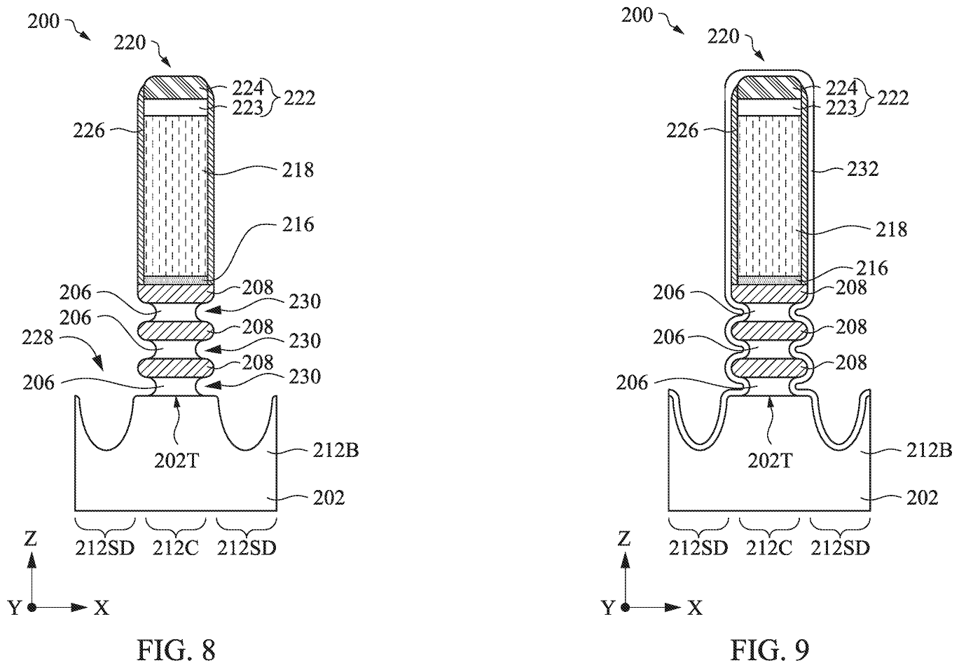

Referring to FIGS. 1, 8, 9, and 10, method 100 includes a block 112 where inner spacer features 234 are formed. While not shown explicitly, operation at block 112 may include selective and partial removal of the sacrificial layers 206 to form inner spacer recesses 230, deposition of inner spacer material 232 over the workpiece 200, and etch back the inner spacer material 232 to form inner spacer features 234 in the inner spacer recesses 230. The sacrificial layers 206 exposed in the source/drain trenches 228 (shown in FIG. 8) are selectively and partially recessed to form inner spacer recesses 230 while the gate spacer layer 226, the exposed portion of the substrate 202, and the channel layers 208 are substantially unetched. In an embodiment where the channel layers 208 consist essentially of silicon (Si) and sacrificial layers 206 consist essentially of silicon germanium (SiGe), the selective recess of the sacrificial layers 206 may be performed using a selective wet etch process or a selective dry etch process. The selective and partial recess of the sacrificial layers 206 may include a SiGe oxidation process followed by a SiGe oxide removal. In that embodiment, the SiGe oxidation process may include use of ozone. In some other embodiments, the selective dry etching process may include use of one or more fluorine-based etchants, such as fluorine gas or hydrofluorocarbons. The selective wet etching process may include an APM etch (e.g., ammonia hydroxide-hydrogen peroxide-water mixture).

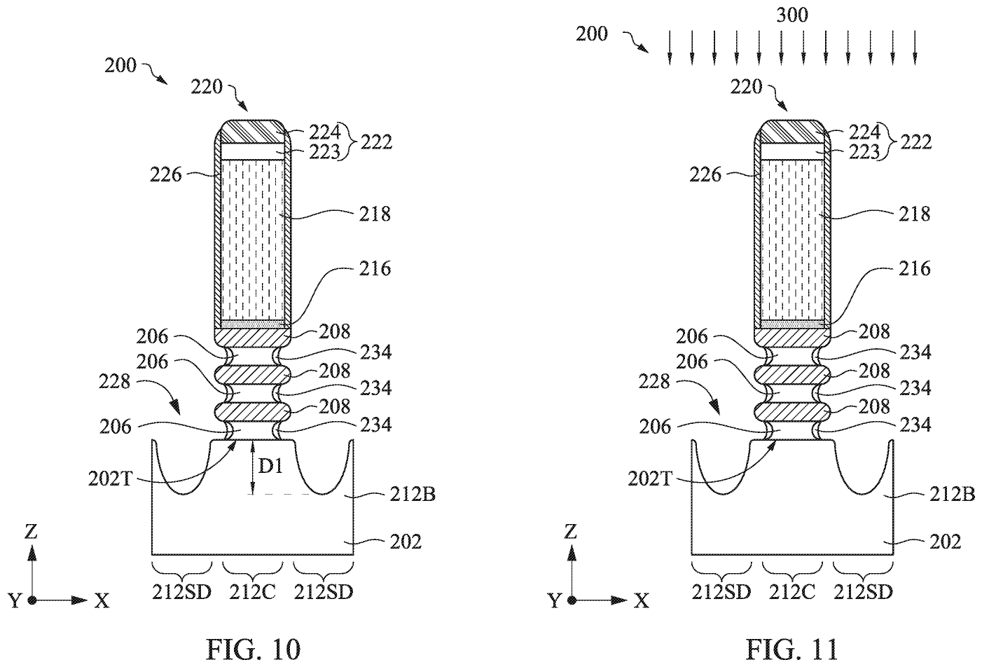

After the inner spacer recesses 230 are formed, the inner spacer material 232 is deposited over the workpiece 200, including over the inner spacer recesses 230, as shown in FIG. 9. The inner spacer material 232 may include metal oxides, silicon oxide, silicon oxycarbonitride, silicon nitride, silicon oxynitride, carbon-rich silicon carbonitride, or a low-k dielectric material. The metal oxides may include aluminum oxide, zirconium oxide, tantalum oxide, yttrium oxide, titanium oxide, lanthanum oxide, or other suitable metal oxide. While not explicitly shown, the inner spacer material 232 may be a single layer or a multilayer. In some implementations, the inner spacer material 232 may be deposited using CVD, PECVD, SACVD, ALD or other suitable methods. The inner spacer material 232 is deposited into the inner spacer recesses 230 as well as over the sidewalls of the channel layers 208 exposed in the source/drain trenches 228. Referring to FIG. 10, the deposited inner spacer material 232 is then etched back to remove the inner spacer material 232 from the sidewalls of the channel layers 208 to form the inner spacer features 234 in the inner spacer recesses 230. At block 112, the inner spacer material 232 may also be removed from the top surfaces and/or sidewalls of the gate-top hard mask layer 222 and the gate spacer layer 226. In some implementations, the etch back operations performed at block 112 may include use of hydrogen fluoride (HF), fluorine gas (F₂), hydrogen (H₂), ammonia (NH₃), nitrogen trifluoride (NF₃), or other fluorine-based etchants. As shown in FIG. 10, each of the inner spacer features 234 is in direct contact with the recessed sacrificial layers 206 and is disposed between two neighboring channel layers 208. In some instances, each of the inner spacer features 234 measures between about 3 nm and about 5 nm thick along the X direction. In the depicted embodiment, each of the inner spacer features 234 has a concave sidewall surface facing the respective source/drain trench 228 (i.e., bending inward towards the respective sacrificial layer 206). Alternatively, the sidewall surface may be flat (e.g., substantially vertical) or convex (i.e., bending outward towards the respective source/drain trench 228). As shown in FIG. 10, while the selective etch process and etch back process at block 112 are selective to the sacrificial layers 206 and the inner spacer material 232, the channel layers 208 are moderately etched and have rounded ends. In the depicted embodiment, the source/drain trench 228 extends a depth D1 into the substrate 202 (measured from the plane 202T) and the depth D1 is between about 3 nm and about 115 nm. A width of the source/drain trench 228 (e.g., as measured between opposing sidewalls of the gate spacer layer 226 on adjacent dummy gate stacks 220 along the X direction) is between about 9 nm to about 32 nm.

Referring to FIGS. 1 and 11, method 100 includes a block 114 where a cleaning process 300 is performed. The cleaning process 300 may include a dry clean, a wet clean, or a combination thereof. In some examples, the wet clean may include use of standard clean 1 (RCA SC-1, a mixture of deionized (D1) water, ammonium hydroxide, and hydrogen peroxide), standard clean 2 (RCA SC-2, a mixture of D1 water, hydrochloric acid, and hydrogen peroxide), SPM (a sulfuric peroxide mixture), and/or hydrofluoric acid for oxide removal. The dry clean process may include helium (He) and hydrogen (H₂) treatment at a temperature between about 250° C. and about 550° C. and under a pressure between about 75 mTorr and about 155 mTorr. The hydrogen treatment may convert silicon on the surface to silane (SiH₄), which may be pumped out for removal. In some implementations, the cleaning process is configured to selectively remove or trim a portion of the channel layers without substantially removing the inner spacer features 234. The cleaning process 300 may remove surface oxide and debris in order to ensure a clean semiconductor surface, which facilitates growth of a base epitaxial layer at block 116.

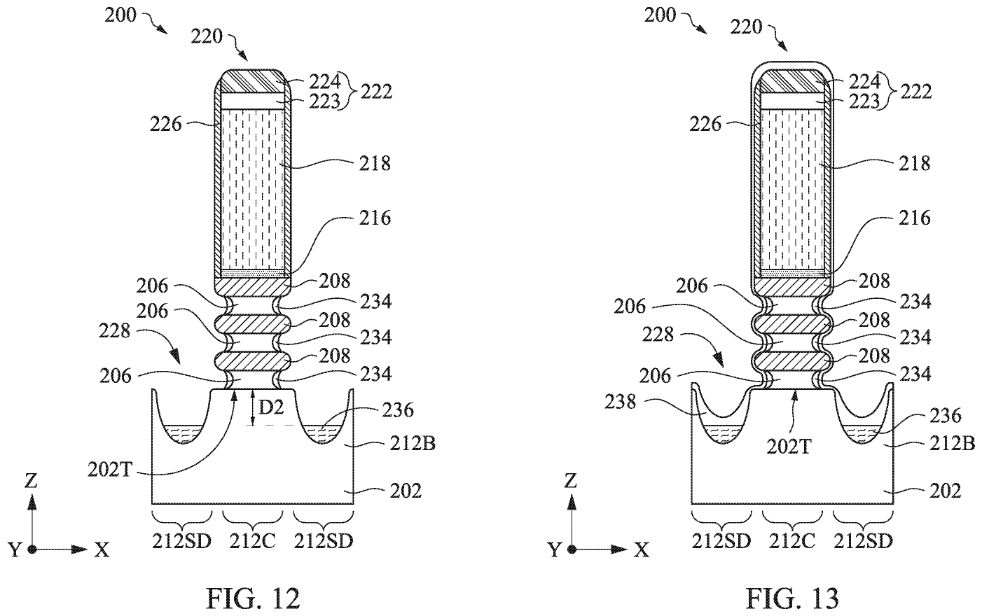

Referring to FIGS. 1 and 12, method 100 includes a block 116 where a base epitaxial layer 236 is deposited in the bottom of the source/drain trench 228. In some embodiments, the base epitaxial layer 236 includes the same material as the substrate 202 and the channel layers 208, such as silicon (Si), except for a dopant condition (doping element and/or doping concentration). For example, the base epitaxial layer 236 is made of non-doped silicon, the substrate 202 is made of doped silicon, and the channel layers 208 are made of non-doped or doped silicon. In some embodiments, the base epitaxial layer 236 includes the same material as the sacrificial layers 206, such as silicon germanium (SiGe), with the germanium (Ge) content the same of different from each other. In some embodiments, the base epitaxial layer 236 includes SiₓGe₁₋ₓ, in which x is between about 0.1 and 1. The germanium content range is not trivial. When the germanium content is greater than about 90%, the lattice mismatch between silicon and germanium may cause too much defect at the interface between the base epitaxial layer 236 and the substrate 202. In other embodiments, the base epitaxial layer 236, the channel layers 208, and the sacrificial layers 206 are made of semiconductor materials different from each other. In various embodiments, the base epitaxial layer 236 is dopant-free, where for example, no intentional doping is performed during the epitaxial growth process. As a comparison, in one instance, the substrate 202 is lightly doped with n-type dopant in the p-type regions for forming PFETs and thus has a higher doping concentration than the base epitaxial layer 236. The dopant-free base epitaxial layer 236 provides a high resistance path from the subsequently formed source/drain features to the substrate 202, such that the leakage current into the substrate 202 is suppressed.

Suitable epitaxial processes for block 116 include vapor-phase epitaxy (VPE), molecular beam epitaxy (MBE), selective CVD, and/or other suitable processes. Various deposition parameters can be tuned to selectively deposit the semiconductor material on exposed semiconductor surfaces in the source/drain trenches 228, such as deposition gas composition, carrier gas composition, deposition gas flow rate, carrier gas flow rate, deposition time, deposition pressure, deposition temperature, source power, RF bias voltage, DC bias voltage, RF bias power, DC bias power, other suitable deposition parameters, or combinations thereof. In some embodiments, the workpiece 200 is exposed to a deposition mixture that includes DCS and/or SiH₄ (silicon-containing precursor), H₂ (carrier precursor), and HCl (etchant-containing precursor) when forming the base epitaxial layer 236. In some embodiments, the selective CVD process implements a deposition temperature of about 600° C. to about 750° C. In some embodiments, the selective CVD process implements a deposition pressure of about 10 Torr to about 100 Torr. In some embodiments, the selective CVD process is configured as a bottom-up deposition process, such that base epitaxial layer 236 grows from the exposed semiconductor surface at the bottom of the source/drain trenches 228, but not from exposed end portions of the channel layers 208. The growth of the base epitaxial layer 236 is under time control such that the top surface of the base epitaxial layer 236 is below the top surface of the fin-shape base 212B (i.e., below the plane 202T). In some embodiments, a post-deposition etch is performed after the selective CVD process to recess the base epitaxial layer 236 below the plane 202T and to remove semiconductor material of the base epitaxial layer 236 that may remain on end portions of the channel layers 208 if any. The post-deposition etch includes a dry etching, a wet etching, other suitable etching process, or combinations thereof. In some embodiments, the base epitaxial layer 236 has a thickness (measured in Z direction) less than about 113 nm, such that a vertical distance D2 from the top surface of the base epitaxial layer 236 to the plane 202T is at least about 2 nm. The thickness range is not trivial. When the base epitaxial layer 236 is thicker than about 113 nm, there may be insufficient upper space remaining in the source/drain trenches 228 to ensure a sufficiently large volume of the subsequently formed source/drain features.

Referring to FIGS. 1, 13, and 14, method 100 includes a block 118 where a dielectric film 240 is formed in the bottom of the source/drain trenches 228 and above the base epitaxial layer 236. While not shown explicitly, operation at block 118 may include deposition of dielectric material 238 over the workpiece 200, and etch back the dielectric material 238 to form the dielectric film 240 in the bottom of the source/drain trenches 228. The dielectric material 238 is deposited over the workpiece 200, including over sidewalls and bottom surfaces of the source/drain trenches 228 and over sidewalls and top surfaces of the dummy gate stack 220, as shown in FIG. 13. In some embodiments, the dielectric material 238 may include a metal oxide or a metal nitride, such as La₂O₃, Al₂O₃, ZnO, ZrN, Zr₂Al₃O₉, TiO₂, TaO₂, ZrO₂, HfO₂, Y₂O₃, AlON, TaCN, other suitable material(s), or combinations thereof. In some embodiments, the dielectric material 238 may include silicon oxide, silicon oxycarbonitride, silicon nitride, silicon oxynitride, carbon-rich silicon carbonitride, or a low-k dielectric material. The dielectric material 238 is selected such that it has a different etch selectivity from the inner spacer features 234, allowing the etching back of the dielectric material 238 without causing etching loss to the inner spacer features 234. In some implementations, the dielectric material 238 may be deposited using a directional deposition process, such as PECVD or other suitable methods. The directional deposition process forms the dielectric material 238 with thicker horizontal portions (e.g., on the bottom surface of the source/drain trenches 228 and the top surface of the dummy gate stack 220) and thinner vertical portions (e.g., on the sidewalls of the dummy gate stack 220 and the fin-shape structure 212).

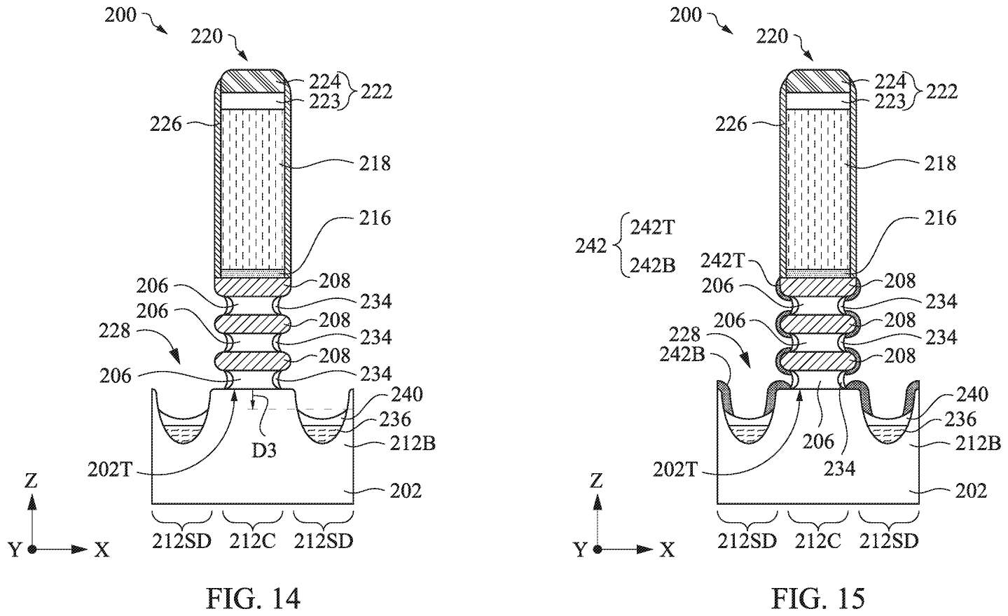

Referring to FIG. 14, the deposited dielectric material 238 is then etched back to remove the thinner vertical portions from the sidewalls of the dummy gate stack 220 and the fin-shape structure 212. In some implementations, the etch back operations performed at block 118 may include use of hydrogen fluoride (HF), fluorine gas (F₂), hydrogen (H₂), ammonia (NH₃), nitrogen trifluoride (NF₃), or other fluorine-based etchants. The thicker horizontal portion atop the dummy gate stack 220 may also be removed due to the loading effect, while the thicker horizontal portion in the bottom of the source/drain trenches 228 is thinned down but still remains as the dielectric film 240, which covers the base epitaxial layer 236. In some embodiments, the dielectric film 240 has a thickness (measured in Z direction) less than about 114 nm. The top surface of the dielectric film 240 is below the plane 202T, such that a top portion of the sidewalls of the fin-shape base 212B is exposed in the source/drain trenches 228. The exposed portion of the sidewalls of the fin-shape base 212B has a vertical distance (D3) to the plane 202T measured along the Z direction between about 1 nm to about 114 nm. Having the top surface of the dielectric film 240 below the plane 202T allows the subsequently formed source/drain features to extend downward into the substrate 202 and benefit from an enlarged volume. In the depicted embodiment, the top surface of the dielectric film 240 has a concave profile.

Referring to FIGS. 1 and 15, method 100 includes a block 120 where a first epitaxial layer 242 is deposited. The first epitaxial layer 242 may be epitaxially and selectively formed from the exposed sidewalls of the channel layers 208 and exposed sidewalls of the substrate 202 (above the dielectric film 240) while sidewalls of the sacrificial layers 206 remain covered by the inner spacer features 234. Suitable epitaxial processes for block 120 include vapor-phase epitaxy (VPE), ultra-high vacuum CVD (UHV-CVD), molecular beam epitaxy (MBE), and/or other suitable processes. The epitaxial growth process at block 120 may use gaseous precursors, which interact with the composition of the substrate 202 as well as the channel layers 208. In some embodiments, parameters of the epitaxial growth process at block 120 are selected such that the first epitaxial layer 242 is not epitaxially deposited on the inner spacer features 234. According to the present disclosure, upon conclusion of the operations at block 120, at least some inner spacer features 234 remain exposed. That is, at least some inner spacer features 234 are not completely covered by the first epitaxial layer 242. In some instances, the first epitaxial layer 242 includes silicon germanium (SiGe) and is doped with a p-type dopant, such as boron (B). In some embodiments, the first epitaxial layer 242 includes a germanium (Ge) content between about 10% and about 40% and a silicon (Si) content between about 90% and about 60%. This germanium (Ge) content range is not trivial. When the germanium content is greater than about 40%, the lattice mismatch between silicon and germanium may cause too much defect at the interface between the first epitaxial layer 242 and the channel layers 208, which may lead to increased resistance or device failure. When the germanium content is smaller than about 10%, the channel layers 208 may not be sufficiently strained for improved hole mobility. A concentration of the p-type dopant in the first epitaxial layer 242 may be between about 1×10²⁰ atoms/cm³ and about 2×10²¹ atoms/cm³. This p-type dopant concentration range is not trivial either. When the doping concentration of the p-type dopant in the first epitaxial layer 242 is lower than about 1×10²⁰ atoms/cm³, the resistance in the first epitaxial layer 242 may prevent satisfactory drive current (i.e., On-state current). When the dopant concentration of the p-type dopant in the first epitaxial layer 242 is greater than about 2×10²¹ atoms/cm³, p-type dopant in the lattice interstices may also cause too much defect at the interface between the first epitaxial layer 242 and the channel layers 208, which may lead to increased resistance.

Still referring to FIG. 15, the first epitaxial layer 242 may include a first substrate portion 242B disposed on the substrate 202 and first channel sidewall portions 242T in contact with the rounded ends of channel layers 208. The first channel sidewall portions 242T wraps over the rounded ends and has a curved shape. In these embodiments, the first channel sidewall portions 236T are formed to a thickness such that the rounded ends are completely covered. In some instances, each of the first channel sidewall portions 242T has a thickness between about 1 nm and about 6 nm along the X direction. In the depicted embodiment as shown in FIG. 15, the first substrate portion 242B does not coalesce or merge with first channel sidewall portions 242T. As such, each of the inner spacer features 234 is not completely covered by the first epitaxial layer 242. That is, while the inner spacer features 234 may come in contact with the first epitaxial layer 242, at least a portion of each of the inner spacer features 234 remain exposed. A portion of the first substrate portion 242B rises above the substrate 202 and covers a top surface of the fin-shape base 212B. The other portion of the first substrate portion 242B extends along the sidewalls of the fin-shape base 212B and reaches the top surface of the dielectric film 240. In the depicted embodiment as shown in FIG. 15, the sidewalls of the fin-shape base 212B as previously exposed in the source/drain trenches 228 are fully covered by the first substrate portion 242B at the conclusion of block 120.

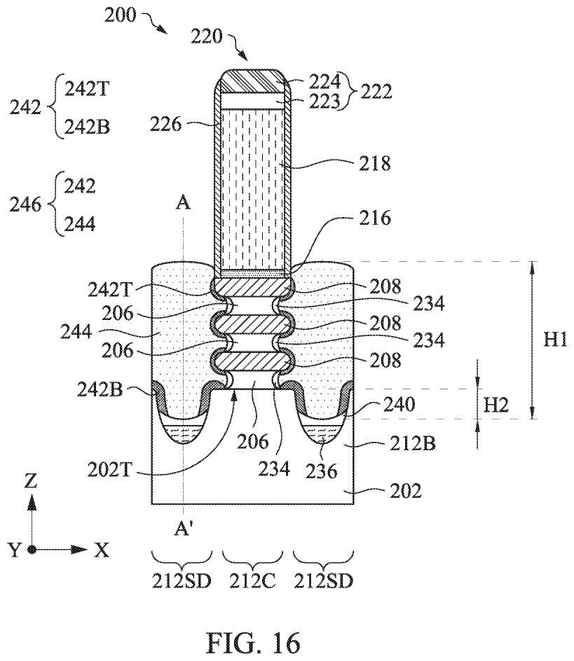

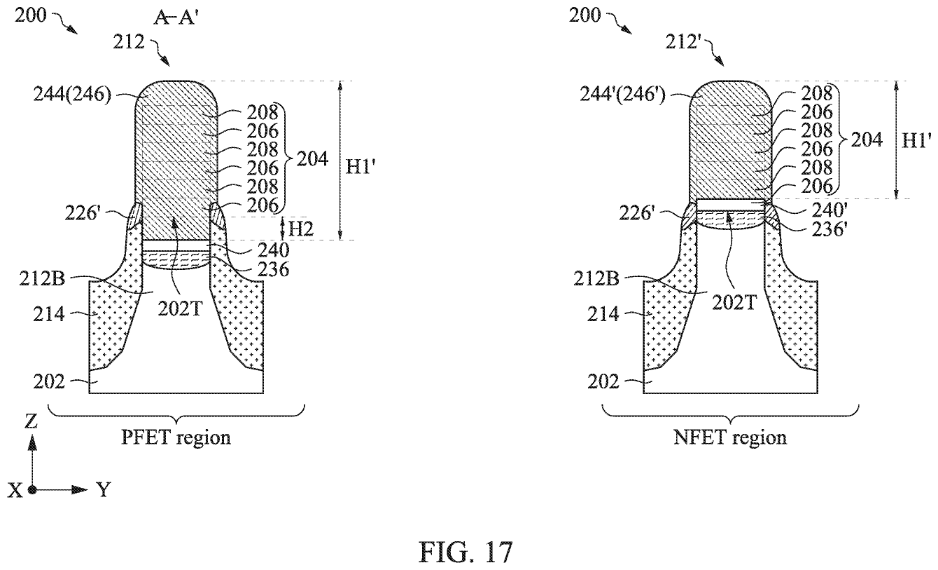

Referring to FIGS. 1, 16, and 17, method 100 includes a block 122 where a second epitaxial layer 244 is deposited over the first epitaxial layer 242. FIG. 17 is a cross-sectional view cut through A-A′ line in FIG. 16. In some embodiments, the second epitaxial layer 244 may be epitaxially and selectively formed from the first epitaxial layer 242. Suitable epitaxial processes for block 122 include vapor-phase epitaxy (VPE), ultra-high vacuum CVD (UHV-CVD), molecular beam epitaxy (MBE), and/or other suitable processes. The epitaxial growth process at block 122 may use gaseous precursors, which interact with the composition of the first epitaxial layer 242. The second epitaxial layer 244 is allowed to overgrow and merge over the inner spacer features 234 and substantially fill the source/drain trenches 228. A top surface of the second epitaxial layer 244 may grow above the top surface of the fin-shape structure 212 (i.e., the top surface of the topmost channel layer 208) and intersect sidewalls of the gate spacer layer 226. In some embodiments, the second epitaxial layer 244 includes silicon germanium (SiGe) doped with a p-type dopant, such as boron (B). The second epitaxial layer 244 serves as a low resistance layer and includes a doping concentration greater than that in the first epitaxial layer 242. In some instances, the doping concentration in the second epitaxial layer 244 may be between about 1×10²⁰ atoms/cm³ and about 3×10²¹ atoms/cm³. When the doping concentration of the p-type dopant in the second epitaxial layer 244 is lower than 1×10²⁰ atoms/cm³, the second epitaxial layer 244 may not be sufficiently conductive to achieve satisfactory drive current (i.e., On-state current). Moreover, solubility of the p-type dopant in the second epitaxial layer 244 may prevent the doping concentration of the p-type dopant to exceed 3×10²¹ atoms/cm³. The doping concentration in the second epitaxial layer 244 is capped by the solubility of boron (B) in the second epitaxial layer 244. Compared to the first epitaxial layer 242, the second epitaxial layer 244 includes a greater germanium content to enhance the strain on the channel layers 208. In some implementations, the second epitaxial layer 244 includes a germanium content between about 20% and about 70% and a silicon content between about 80% and about 30%. Compared to the second epitaxial layer 244, the base epitaxial layer 236 may include a greater germanium content. In an alternative embodiment, compared to the first epitaxial layer 242, the base epitaxial layer 236 may include a less germanium content. According to the present disclosure, a volume of the second epitaxial layer 244 is greater than a volume of the first epitaxial layer 242. In this regard, the second epitaxial layer 244 is thicker than the first epitaxial layer 242. In some embodiments, the second epitaxial layer 244 may have a width measured between about 9 nm and about 32 nm along the X direction.

In the depicted embodiment as shown in FIG. 16, a bottom portion of the second substrate portion 242B extends along the sidewalls of the first substrate portion 242B and reaches the top surface of the dielectric film 240. The second epitaxial layer 244 is separated or spaced apart from the channel layers 208 by the first epitaxial layer 242 and separated or spaced apart from the base epitaxial layer 236 by the dielectric film 240. The first epitaxial layer 242 and the second epitaxial layer 244 in a source/drain region 212SD may be collectively referred to as a source/drain feature 246. In some implementations, a height (H1) of the source/drain feature 246 measured from top to bottom along the Z direction is between about 20 nm and 105 nm, and a portion of the source/drain feature 246 below the plane 202T has a height (H2) measured along the Z direction between about 1 nm to about 20 nm.

In the depicted embodiment as shown in FIG. 17, in the PFET region (where p-type transistors are formed), the gate spacer layer 226 formed at block 108 is also deposited on sidewalls of the fin-shape structure 212 in the source/drain region 212SD. The portion of the gate spacer layer 226 in the source/drain region 212SD is also referred to as the fin spacer layer 226′. The fin spacer layer 226′ confines the epitaxial growth of the second epitaxial layer 244. After the fin-shape structure 212 is recessed at block 110 and the second epitaxial layer 244 is epitaxially grown at block 122, the fin spacer layer 226′ is over sidewalls of the second epitaxial layer 244. The etching process at block 110 also recesses the STI feature 214. The fin spacer layer 226′ may protect a portion of the STI feature 214 directly thereunder from etching loss, while other portions of the STI feature 214 is recessed. A bottom surface of the base epitaxial layer 236 may be above the recessed top surface of the STI feature 214. A top surface of the dielectric film 240 may be below the topmost portion of the STI feature 214 and above the recessed top surface of the STI feature 214. For clarity of the spatial relationship, the channel layers 208 and the sacrificial layers 206 in the channel region are overlayed in FIG. 17, as represented by boxes of dashed lines.

Still referring to FIG. 17, a cross-sectional view cut through a source/drain region in an NFET region (where n-type transistors are formed) is also depicted for the sake of comparison. The base epitaxial layer 236′ and the dielectric film 240′ in the NFET region are positioned higher than their respective counterparts in the PFET region. For example, the top surface of the dielectric film 240′ in the NFET region may be aligned with the bottom surface of the bottommost channel layer 208, such that the height (H1′) of the source/drain feature 246′ in the NFET region is measured from the bottom surface of the bottommost channel layer 208 and smaller than the height H1 in the PFET region. Accordingly, the source/drain feature 246′ in the NFET region is above the plane 202T. A volume of the source/drain feature 246′ in the NFET region may also be smaller than the source/drain feature 246 in the PFET region. The larger volume of the source/drain features 246 in the PFET region helps maintaining a compressive strain to the channel layers 208 in the p-type transistors.

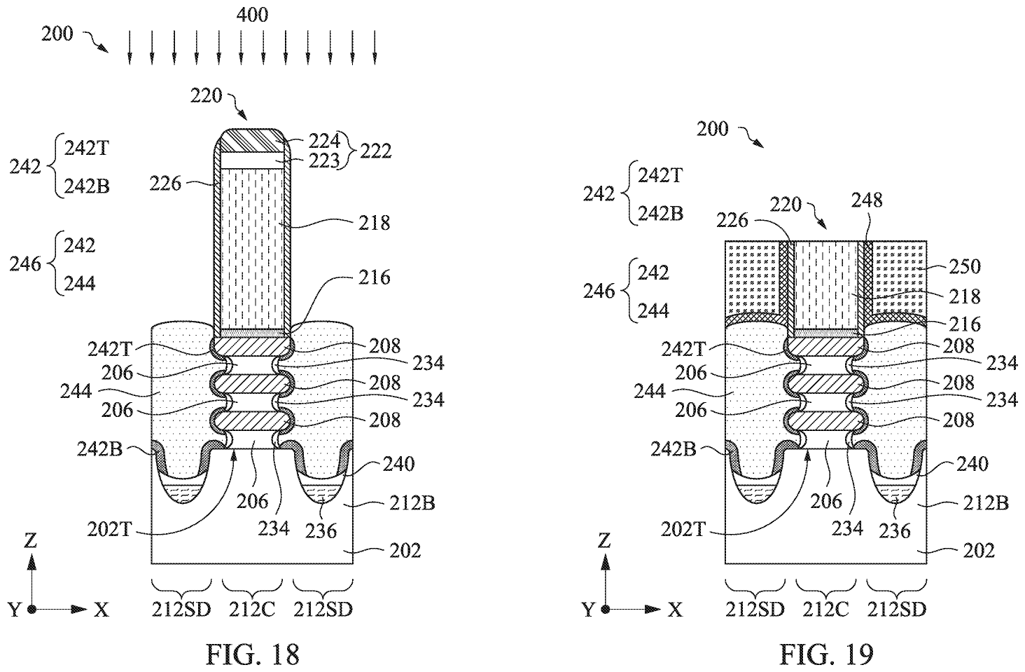

Referring to FIGS. 1 and 18, method 100 includes a block 124 where the workpiece 200 is annealed in an anneal process 400. In some implementation, the anneal process 400 may include a rapid thermal anneal (RTA) process, a laser spike anneal process, a flash anneal process, or a furnace anneal process. The anneal process 400 may include a peak anneal temperature between about 900° C. and about 1000° C. In these implementations, the peak anneal temperature may be maintained for a duration measured by seconds or microseconds. Through the anneal process 400, a desired electronic contribution of the p-type dopant in the semiconductor host, such as silicon germanium (SiGe) or germanium (Ge), may be obtained. The anneal process 400 may generate vacancies that facilitate movement of the p-type dopant from interstitial sites to substitutional lattice sites and reduce damages or defects in the lattice of the semiconductor host.

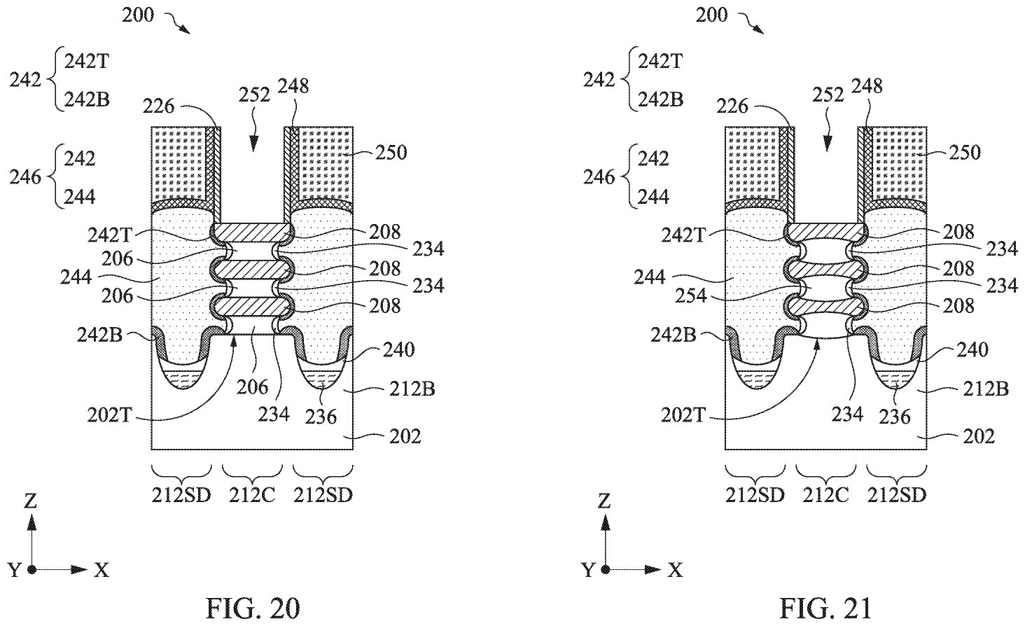

Referring to FIGS. 1 and 19-22, method 100 includes a block 126 where further processes are performed. Such further processes may include, for example, deposition of a contact etch stop layer (CESL) 248 over the workpiece 200 (shown in FIG. 19), deposition of an interlayer dielectric (ILD) layer 250 over the CESL 248 (shown in FIG. 19), removal of the dummy gate stack 220 (shown in FIG. 20), selective removal of the sacrificial layers 206 in the channel region 212C to release the channel layers 208 as channel members (shown in FIG. 21), and formation of a gate structure 256 over the channel region 212C (shown in FIG. 21). Referring now to FIG. 19, the CESL 248 is formed prior to forming the ILD layer 250. In some examples, the CESL 248 includes silicon nitride, silicon oxynitride, and/or other materials known in the art. The CESL 248 may be formed by ALD, plasma-enhanced chemical vapor deposition (PECVD) process and/or other suitable deposition processes. The ILD layer 250 is then deposited over the CESL 248. In some embodiments, the ILD layer 250 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 250 may be deposited by a PECVD process or other suitable deposition technique. In some embodiments, after formation of the ILD layer 250, the workpiece 200 may be annealed to improve integrity of the ILD layer 250. As shown in FIG. 19, the CESL 248 is disposed directly on top surfaces of the source/drain feature 246.

Referring to FIGS. 19 and 20, after the deposition of the CESL 248 and the ILD layer 250, the workpiece 200 may be planarized by a planarization process to expose the dummy gate stack 220. For example, the planarization process may include a chemical mechanical planarization (CMP) process. After the CMP process, a distance from the top surface of the dummy gate stack 220 to the top surface of the topmost channel layer 208 may measure between 5 nm and about 50 nm along the Z direction. Exposure of the dummy gate stack 220 allows the removal of the dummy gate stack 220 and release of the channel layers 208, illustrated in FIG. 20. In some embodiments, the removal of the dummy gate stack 220 results in a gate trench 252 over the channel regions 212C. The removal of the dummy gate stack 220 may include one or more etching processes that are selective to the material of the dummy gate stack 220. For example, the removal of the dummy gate stack 220 may be performed using as a selective wet etch, a selective dry etch, or a combination thereof that is selective to the dummy gate stack 220. After the removal of the dummy gate stack 220, sidewalls of the channel layers 208 and the sacrificial layers 206 in the channel region 212C are exposed in the gate trench 252.

Referring to FIG. 21, after the removal of the dummy gate stack 220, the method 100 may include operations to selectively remove the sacrificial layers 206 between the channel layers 208 in the channel region 212C. The selective removal of the sacrificial layers 206 releases the channel layers 208 to form channel members (also numbered as 208). The selective removal of the sacrificial layers 206 also leaves behind space 254 between channel members 208. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture).

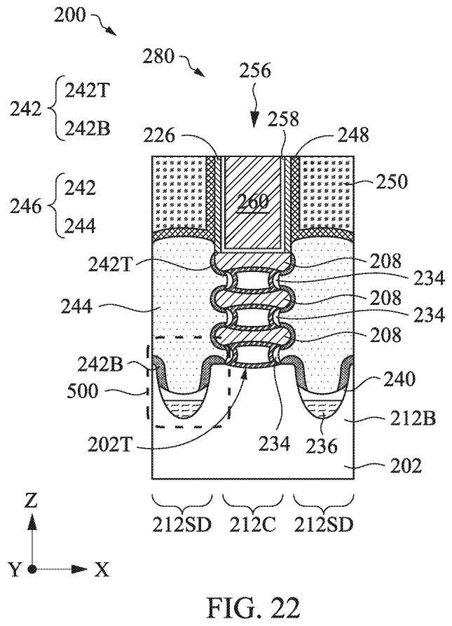

Referring to FIG. 22, the method 100 may include further operations to form the gate structure 256 to wrap around each of the channel members 208. In some embodiments, the gate structure 256 is formed within the gate trench 252 and into the space 254 left behind by the removal of the sacrificial layers 206. In this regard, the gate structure 256 wraps around each of the channel members 208. The gate structure 256 includes a gate dielectric layer 258 and a gate electrode layer 260 over the gate dielectric layer 258. In some embodiments, while not explicitly shown in the figures, the gate dielectric layer 258 includes an interfacial layer and a high-K gate dielectric layer. High-K dielectric materials, as used and described herein, include dielectric materials having a high dielectric constant, for example, greater than that of thermal silicon oxide (˜3.9). The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The high-K gate dielectric layer may include hafnium oxide. Alternatively, the high-K gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The high-K gate dielectric layer may be formed by ALD, physical vapor deposition (PVD), CVD, oxidation, and/or other suitable methods.

The gate electrode layer 260 of the gate structure 256 may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer 260 may include titanium nitride (TIN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer 260 may be formed by ALD, PVD. CVD, e-beam evaporation, or other suitable process. In various embodiments, a CMP process may be performed to remove excessive metal, thereby providing a substantially planar top surface of the gate structure 256. The gate structure 256 includes portions that interpose between channel members 208 in the channel region 212C.

Still referring to FIG. 22, upon conclusion of the operations at block 126, a transistor 280, particularly a p-type transistor 280, is substantially formed. The transistor 280 includes channel members 208 that are vertically stacked along the Z direction. Each of the channel members 208 is wrapped around by the gate structure 256. The channel members 208 extend or are sandwiched between two source/drain features 246 along the X direction. Each of the source/drain features 246 includes the first epitaxial layer 242 in contact with the sidewalls of the fin-shape base 212B and the channel members 208, the second epitaxial layer 244 in contact with the first epitaxial layer 242. The second epitaxial layer 244 is spaced apart from the channel members 208 by the first epitaxial layers 242. Underneath the source/drain features 246 are the dielectric film 240 and the base epitaxial layer 236. The dielectric film 240 and the base epitaxial layer 236 exhibit high resistivity, thus providing a high resistance path from the source/drain features 246 to the substrate 202, such that the leakage current into the substrate 202 is suppressed. The dielectric film 240 and the base epitaxial layer 236 are below the plane 202T (also considered as the top surface of the fin-shape base 212B, or the top surface of the substrate 202) for certain distance along the Z direction, allowing the bottom portion of the source/drain features 246 extends further downward and below the plane 202T. The volume of the source/drain features 246 is thus expanded and the compressive strain provided to the channel members 208 is not compromised.

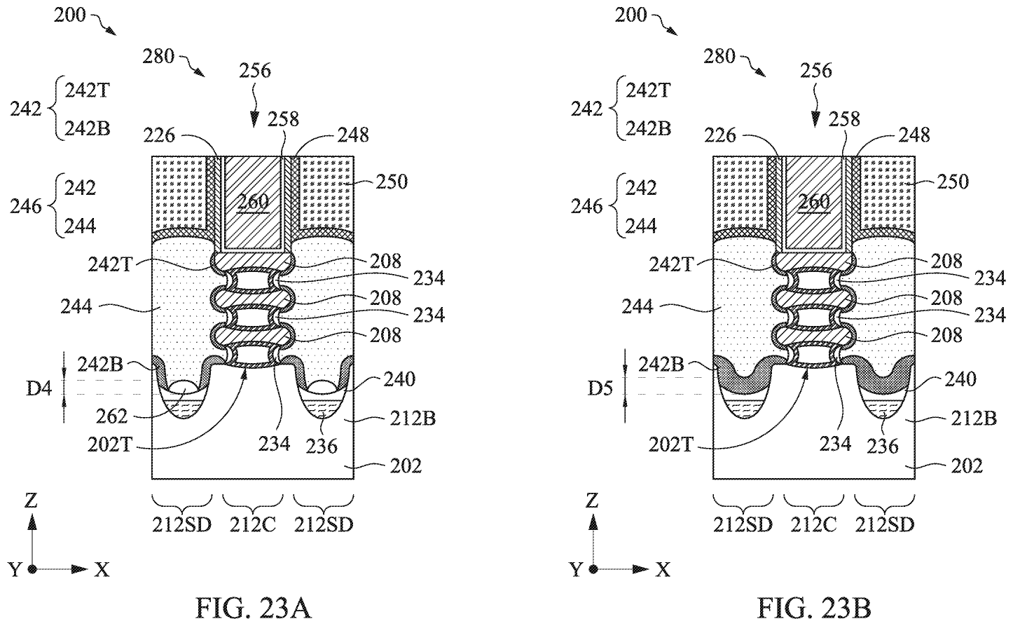

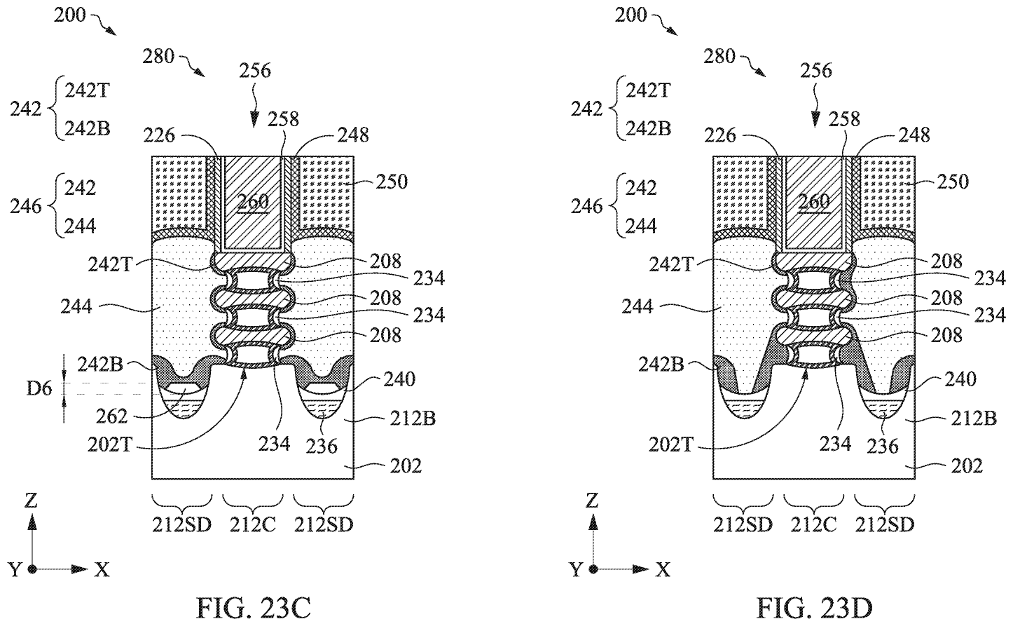

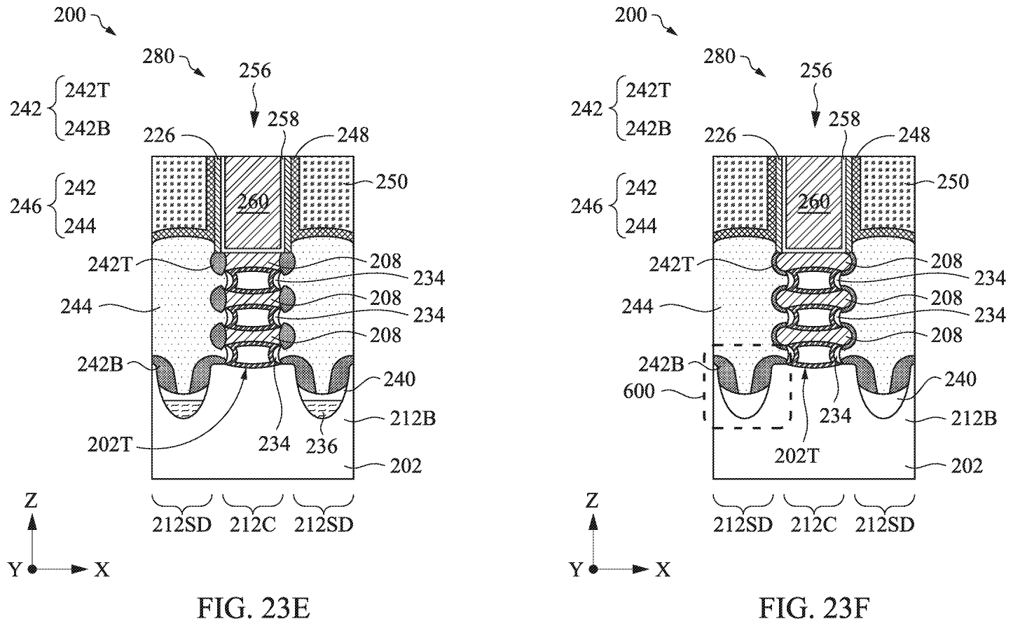

An alternative embodiment of the transistor 280 is illustrated in FIG. 23A. Many aspects of the transistors 280 in FIGS. 22 and 23A are the same or similar. For clarity and case of reference, reference numerals for the same or similar features are repeated. One difference is that for the depicted embodiment as in FIG. 23A, the epitaxial growth process at block 122 may leave a void (or referred to as air pocket) 262 between the second epitaxial layer 244 and the dielectric film 240. During the epitaxial growth process at block 122, the second epitaxial layer 244 may exhibit a faster growth rate from the semiconductor surface of the first substrate portion 242B and a much slower or substantially zero growth rate from the top surface of the dielectric film 240, such that the second epitaxial layer 244 from two opposing sides of the first substrate portions 242B may merge above the dielectric film 240 and seal the void 262 thereunder. The void 262 may have a height (D4) between about 1 nm to about 10 nm measured along the Z direction. In the depicted embodiment as shown in FIG. 23A, the second epitaxial layer 244 is spaced apart from the dielectric film 240 by the void 262. Exposed in the void 262, a bottom surface of the second epitaxial layer 244 may have a concave profile that bends upward.

An alternative embodiment of the transistor 280 is illustrated in FIG. 23B. Many aspects of the transistors 280 in FIGS. 22 and 23B are the same or similar. For clarity and case of reference, reference numerals for the same or similar features are repeated. One difference is that for the depicted embodiment as in FIG. 23B, the two opposing first substrate portions 242B may merge and fully cover the top surface of the dielectric film 240. The merged first substrate portions 242B has a thickness (D5) along the Z direction between about 1 nm and about 30 nm. The second epitaxial layer 244 is spaced apart from the dielectric film 240 by the first substrate portion 242B. A bottom portion of the second epitaxial layer 244 may still extend under the plane 202T.

An alternative embodiment of the transistor 280 is illustrated in FIG. 23C. Many aspects of the transistors 280 in FIGS. 23B and 23C are the same or similar. For clarity and case of reference, reference numerals for the same or similar features are repeated. One difference is that for the depicted embodiment as in FIG. 23C, the epitaxial growth process at block 120 may leave a void (or referred to as air pocket) 262 between the merged first substrate portions 242B and the dielectric film 240. During the epitaxial growth process at block 120, the first substrate portions 242B may exhibit a faster growth rate from the semiconductor sidewall surfaces of the fin-shape base 212B and a much slower or substantially zero growth rate from the top surface of the dielectric film 240, such that the two first substrate portions 242B from opposing sidewalls of the fin-shape base 212B may merge above the dielectric film 240 and seal the void 262 thereunder. The void 262 may have a height (D6) between about 1 nm to about 10 nm measured along the Z direction. In the depicted embodiment as shown in FIG. 23C, exposed in the void 262, a bottom surface of the merged first substrate portions 242B may have a concave profile that bends upward.

An alternative embodiment of the transistor 280 is illustrated in FIG. 23D. Many aspects of the transistors 280 in FIGS. 22 and 23D are the same or similar. For clarity and ease of reference, reference numerals for the same or similar features are repeated. One difference is that for the depicted embodiment as in FIG. 23D, the first substrate portions 242B may merge with the bottommost first channel sidewall portions 242T in contact with the bottommost channel layer 208. By extending between the substrate 202 and the bottommost channel layer 208, the first substrate portion 242B also completely covers the bottommost inner spacer features 234. Also as depicted in FIG. 23D, two adjacent first channel sidewall portions 242T may also merge and completely cover the respective inner spacer feature 234 therebetween. Also, although not depicted in FIG. 23D, the two opposing first substrate portions 242B may also merge as illustrated in FIG. 23B, and voids 262 may also be formed as illustrated in FIG. 23A and FIG. 23C.

An alternative embodiment of the transistor 280 is illustrated in FIG. 23E. Many aspects of the transistors 280 in FIGS. 22 and 23E are the same or similar. For clarity and ease of reference, reference numerals for the same or similar features are repeated. One difference is that for the depicted embodiment as in FIG. 23E, the channel layers 208 are laterally recessed prior to the epitaxial growth process at block 120. In an embodiment where the channel layers 208 consist essentially of silicon (Si) and sacrificial layers 206 consist essentially of silicon germanium (SiGe), the selective recess of the channel layers 208 may be performed using a selective wet etch process or a selective dry etch process that is tuned to have an etch contrast between silicon and silicon germanium. The lateral recessing of the channel layers 208 shortens the length of the channel layers 208, such that the portion of the channel layers 208 under the gate structure 256's effective control increases, which improves gate control of the channel region. The lateral recessing of the channel layers 208 converts the otherwise rounded ends of the channel layers 208 to a concave profile that bend inward towards the gate structure 256. The variations in the epitaxial features 246 as illustrated in FIGS. 23A-23D can also apply to the depicted embodiment as shown in FIG. 23E.

An alternative embodiment of the transistor 280 is illustrated in FIG. 23F. Many aspects of the transistors 280 in FIGS. 22 and 23F are the same or similar. For clarity and ease of reference, reference numerals for the same or similar features are repeated. One difference is that for the depicted embodiment as in FIG. 23F, the formation of the base epitaxial layer 236 at block 116 is skipped, such that the dielectric film 240 is directly formed in the bottom of the source/drain trenches 228 and atop the top surface of the substrate 202. The variations in the source/drain features 246 and the channel layers 208 as illustrated in FIGS. 23A-23E can also apply to the depicted embodiment as shown in FIG. 23F.

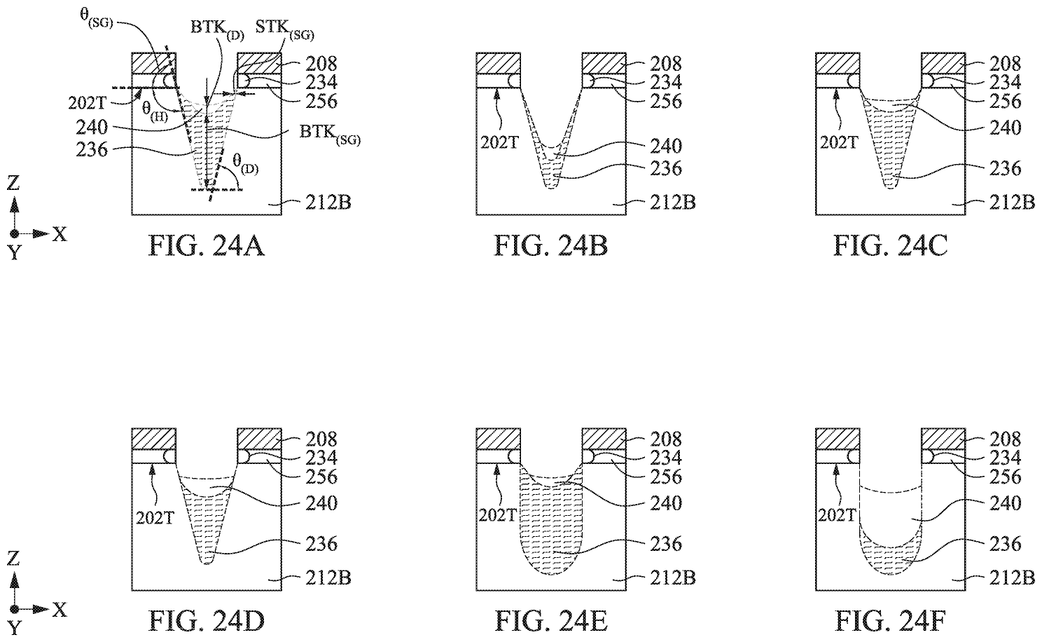

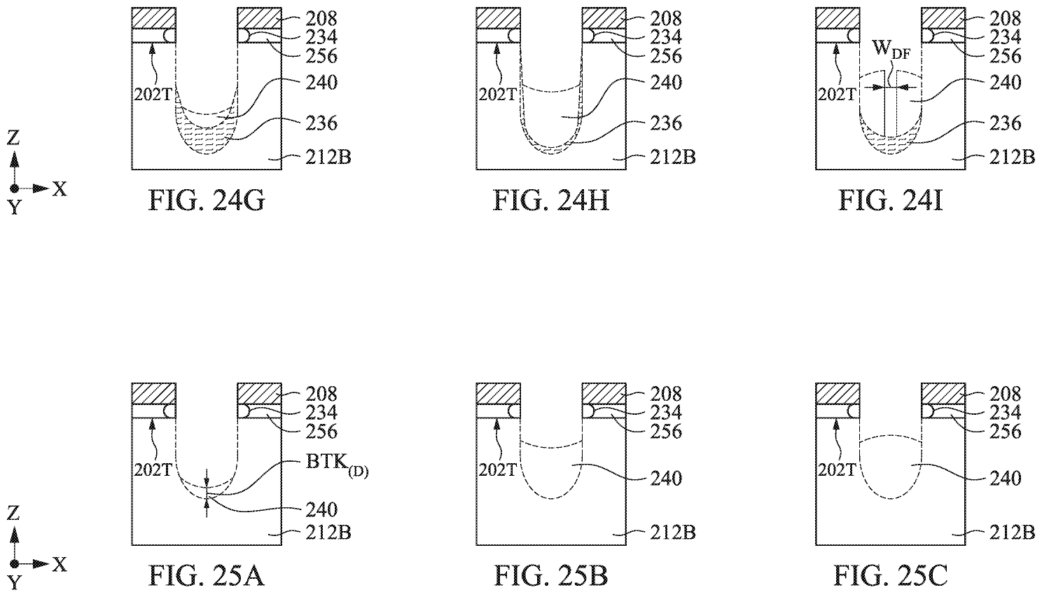

FIGS. 24A-24I illustrate alternative embodiments of a region 500 in FIG. 22 (as well as in FIGS. 23A-23E). The region 500 includes the bottom portion of the source/drain trench 228 that is below the bottommost inner spacer feature 234 and the base epitaxial layer 236 and the dielectric film 240 formed therein. For clarity and ease of reference, the source/drain feature 246 is omitted in FIGS. 24A-24I but still exists. In each alternative embodiment, the sidewall of the source/drain trench 228 has an angle θ_{(H)} with respect to the plane 202T measured between about 45° and about 180°; the base epitaxial layer 236 has a top surface that forms an angle (SG) with respect to the plane 202T measured between about 0° and about 90°; the base epitaxial layer 236 has a sidewall surface that forms an angle θ (D) with respect to the plane 202T measured between about 0° and about 90°; the base epitaxial layer 236 has a bottom thickness (or center thickness) BTK_{(SG)} measured between about 1 nm and about 115 nm; the base epitaxial layer 236 has a sidewall thickness STK_{(sG)} between about 0.5 nm and about 32 nm; the dielectric film 240 has a bottom thickness (or center thickness) BTK_{(D)} between about 0.5 nm to about 115 nm. The source/drain trench 228 may have a U-shape profile, a V-shape profile, a transitional profile between U-shape and V-shape, or other shapes. The V-shape profile may show (111) or (110) facets of silicon crystal. The V-shape profile may be formed by an anisotropic etching process with radicals selectively etching the (100) planes over the (111) planes or the (110) planes. In some cases, the etch rate of the (100) planes may be about three times greater than the etch rate of the (111) planes. Due to this selectivity, the etching by the radicals may tend to slow or stop along the (111) planes or the (110) planes of silicon during the second patterning process and thus form the V-shape profile. In each alternative embodiment, the top surface of the dielectric film 240 is below the plane 202T, allowing the source/drain feature 246 to extend below the plane 202T.

In FIG. 24A, the source/drain trench 228 has a V-shape profile. The base epitaxial layer 236 may completely cover the sidewalls of the source/drain trench 228. The dielectric film 240 is disposed in the concave profile of the base epitaxial layer 236. Edge portions of the base epitaxial layer 236 may be above the topmost portion of the dielectric film 240. The bottom thickness BTK_{(SG)} of the base epitaxial layer 236 is larger than half of the depth of the source/drain trench 228. The bottom thickness BTK_{(SG)} of the base epitaxial layer 236 is larger than the bottom thickness BTK_{(D)} of the dielectric film 240.

In FIG. 24B, the source/drain trench 228 has a V-shape profile. The base epitaxial layer 236 may completely cover the sidewalls of the source/drain trench 228. The dielectric film 240 is disposed in the concave profile of the base epitaxial layer 236. Edge portions of the base epitaxial layer 236 may be above the topmost portion of the dielectric film 240. The bottom thickness BTK_{(SG)} of the base epitaxial layer 236 is smaller than half of the depth of the source/drain trench 228. The bottom thickness BTK_{(SG)} of the base epitaxial layer 236 is larger than the bottom thickness BTK_{(D)} of the dielectric film 240.

In FIG. 24C, the source/drain trench 228 has a transitional profile between V-shape and U-shape. The base epitaxial layer 236 may completely cover the sidewalls of the source/drain trench 228. The dielectric film 240 is disposed in the concave profile of the base epitaxial layer 236. Edge portions of the base epitaxial layer 236 may be above the topmost portion of the dielectric film 240. The bottom thickness BTK_{(SG)} of the base epitaxial layer 236 is larger than half of the depth of the source/drain trench 228. The bottom thickness BTK_{(SG)} of the base epitaxial layer 236 is larger than the bottom thickness BTK_{(D)} of the dielectric film 240.

In FIG. 24D, the source/drain trench 228 has a transitional profile between V-shape and U-shape. The base epitaxial layer 236 does not completely cover the sidewalls of the source/drain trench 228. The dielectric film 240 is disposed in the concave profile of the base epitaxial layer 236. Edge portions of the base epitaxial layer 236 may be leveled with the topmost portion of the dielectric film 240. The bottom thickness BTK_{(SG)} of the base epitaxial layer 236 is larger than half of the depth of the source/drain trench 228. The bottom thickness BTK_{(SG)} of the base epitaxial layer 236 is larger than the bottom thickness BTK_{(D)} of the dielectric film 240.

In FIG. 24E, the source/drain trench 228 has a U-shape profile. The base epitaxial layer 236 may completely cover the sidewalls of the source/drain trench 228. The dielectric film 240 is disposed in the concave profile of the base epitaxial layer 236. Edge portions of the base epitaxial layer 236 may be above the topmost portion of the dielectric film 240. The bottom thickness BTK_{(SG)} of the base epitaxial layer 236 is larger than half of the depth of the source/drain trench 228. The bottom thickness BTK_{(SG)} of the base epitaxial layer 236 is larger than the bottom thickness BTK_{(D)} of the dielectric film 240.

In FIG. 24F, the source/drain trench 228 has a U-shape profile. The base epitaxial layer 236 does not completely cover the sidewalls of the source/drain trench 228. The dielectric film 240 is disposed over and completely covers the top surface of the base epitaxial layer 236. The bottom thickness BTK_{(SG)} of the base epitaxial layer 236 is smaller than half of the depth of the source/drain trench 228. The bottom thickness BTK_{(SG)} of the base epitaxial layer 236 is smaller than the bottom thickness BTK_{(D)} of the dielectric film 240.

In FIG. 24G, the source/drain trench 228 has a U-shape profile. The base epitaxial layer 236 does not completely cover the sidewalls of the source/drain trench 228. The dielectric film 240 is disposed in the concave profile of the base epitaxial layer 236. Edge portions of the base epitaxial layer 236 may be above the topmost portion of the dielectric film 240. The bottom thickness BTK_{(SG)} of the base epitaxial layer 236 is smaller than half of the depth of the source/drain trench 228. The bottom thickness BTK_{(SG)} of the base epitaxial layer 236 is larger than the bottom thickness BTK_{(D)} of the dielectric film 240.

In FIG. 24H, the source/drain trench 228 has a U-shape profile. The base epitaxial layer 236 may completely cover the sidewalls of the source/drain trench 228. The dielectric film 240 is disposed in the concave profile of the base epitaxial layer 236. Edge portions of the base epitaxial layer 236 may be above the topmost portion of the dielectric film 240. The bottom thickness BTK_{(SG)} of the base epitaxial layer 236 is smaller than half of the depth of the source/drain trench 228. The bottom thickness BTK_{(SG)} of the base epitaxial layer 236 is smaller than the bottom thickness BTK_{(D)} of the dielectric film 240.

In FIG. 24I, the source/drain trench 228 has a U-shape profile. The base epitaxial layer 236 does not completely cover the sidewalls of the source/drain trench 228. The dielectric film 240 is disposed over the top surface of the base epitaxial layer 236. The bottom thickness BTK_{(SG)} of the base epitaxial layer 236 is smaller than half of the depth of the source/drain trench 228. The bottom thickness BTK_{(SG)} of the base epitaxial layer 236 is smaller than the bottom thickness BTK_{(D)} of the dielectric film 240. Further, during the etch back process of the dielectric film 240, the dielectric film 240 may be etched through and divided into two portions. The gap width (W_{DF}) between the two portions is between about 0.1 nm and 32 nm in some implementations. A void may be sealed under the source/drain feature 246 and laterally between the divided portions of the dielectric film 240. The source/drain feature 246 may also extend downward into the gap between the divided portions of the dielectric film 240.

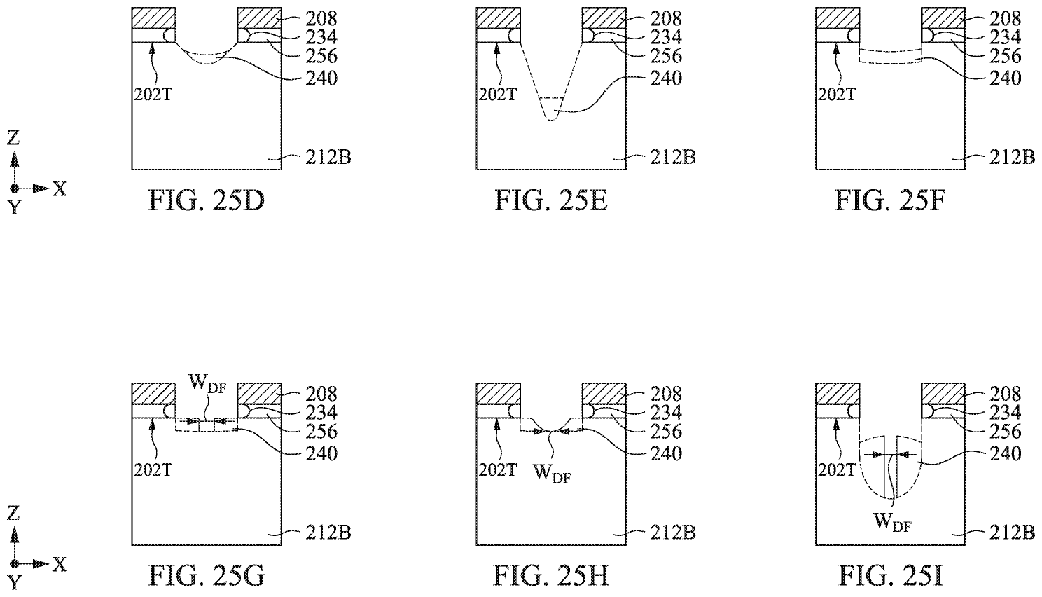

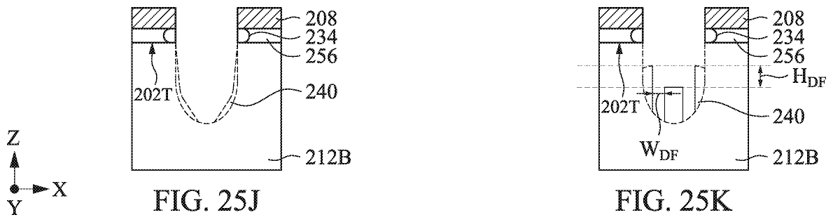

FIGS. 25A-25K illustrate alternative embodiments of a region 600 in FIG. 23F. The region 600 includes the bottom portion of the source/drain trench 228 that is below the bottommost inner spacer feature 234 and the dielectric film 240 formed therein. The base epitaxial layer 236 is not formed as block 116 is skipped. The bottom thickness BTK_{(D)} of the dielectric film 240 is between about 1 nm and about 114 nm in some implementations. For clarity and case of reference, the source/drain feature 246 is omitted in FIGS. 25A-25K but still exists. Similar to the discussion above in association with FIGS. 24A-24I, the source/drain trench 228 may have a U-shape profile, a V-shape profile, a transitional profile between U-shape and V-shape, or other shapes.

In FIG. 25A, the source/drain trench 228 has a U-shape profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is less than half of the depth of the source/drain trench 228. A top surface of the dielectric film 240 has a concave profile.

In FIG. 25B, the source/drain trench 228 has a U-shape profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is larger than half of the depth of the source/drain trench 228. A top surface of the dielectric film 240 has a concave profile.

In FIG. 25C, the source/drain trench 228 has a U-shape profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is larger than half of the depth of the source/drain trench 228. A top surface of the dielectric film 240 has a convex profile. The convex profile is formed due to particular parameters applied in the etch back process.

In FIG. 25D, the source/drain trench 228 has a dish-shape profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is smaller or larger than half of the depth of the source/drain trench 228. A top surface of the dielectric film 240 has a concave profile.

In FIG. 25E, the source/drain trench 228 has a V-shape profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is smaller than half of the depth of the source/drain trench 228. A top surface of the dielectric film 240 is substantially flat.

In FIG. 25F, the source/drain trench 228 has a rectangular profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is smaller or larger than half of the depth of the source/drain trench 228. A top surface of the dielectric film 240 is substantially flat.

In FIG. 25G, the source/drain trench 228 has a rectangular profile. The dielectric film 240 is disposed in the bottom of the source/drain trench 228. The dielectric film 240 may completely cover the sidewalls of the source/drain trench 228. The bottom thickness BTK_{(D)} of the dielectric film 240 roughly equals the depth of the source/drain trench 228. A top surface of the dielectric film 240 is substantially flat. Further, during the etch back process of the dielectric film 240, the dielectric film 240 may be etched through and divided into two portions. The gap width (W_{DF}) between the two portions is between about 0.1 nm and 32 nm in some implementations. The opposing sidewalls of the divided portions may be substantially vertical. A void may be sealed under the source/drain feature 246 and laterally between the divided portions of the dielectric film 240. The source/drain feature 246 may also extend downward into the gap between the divided portions of the dielectric film 240.

In FIG. 25H, the source/drain trench 228 has a rectangular profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is smaller or larger than half of the depth of the source/drain trench 228. A top surface of the dielectric film 240 is substantially flat. Further, during the etch back process of the dielectric film 240, the dielectric film 240 may be etched through and divided into two portions. The gap width (W_{DF}) between the two portions is between about 0.1 nm and 32 nm in some implementations. The opposing sidewalls of the divided portions may be slanted with an angle with respect to the plane 202T measured between about 80° and about 179°. A void may be sealed under the source/drain feature 246 and laterally between the divided portions of the dielectric film 240. The source/drain feature 246 may also extend downward into the gap between the divided portions of the dielectric film 240.

In FIG. 25J, the source/drain trench 228 has a U-shape profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is larger than half of the depth of the source/drain trench 228. A top surface of the dielectric film 240 has a convex profile. Further, during the etch back process of the dielectric film 240, the dielectric film 240 may be etched through and divided into two portions. The gap width (W_{DF}) between the two portions is between about 0.1 nm and 32 nm in some implementations. The opposing sidewalls of the divided portions may be substantially vertical. A void may be sealed under the source/drain feature 246 and laterally between the divided portions of the dielectric film 240. The source/drain feature 246 may also extend downward into the gap between the divided portions of the dielectric film 240.

In FIG. 25J, the source/drain trench 228 has a U-shape profile. The dielectric film 240 is disposed in the bottom of the source/drain trench 228. The dielectric film 240 may completely cover the sidewalls of the source/drain trench 228. The bottom thickness BTK_{(D)} of the dielectric film 240 is smaller than half of the depth of the source/drain trench 228. A top surface of the dielectric film 240 has a concave profile. Further, during the etch back process of the dielectric film 240, the dielectric film 240 may be etched through and divided into two portions. The gap width (W_{DF}) between the two portions is between about 0.1 nm and 32 nm in some implementations. A void May be sealed under the source/drain feature 246 and laterally between the divided portions of the dielectric film 240. The source/drain feature 246 may also extend downward into the gap between the divided portions of the dielectric film 240 and may even have physical contact with the substrate 202 due to the small thickness of the dielectric film 240 in the depicted embodiment as shown in FIG. 25J.

In FIG. 25K, the source/drain trench 228 has a U-shape profile. The dielectric film 240 is disposed in the bottom of the source/drain trench 228. The dielectric film 240 does not completely cover the sidewalls of the source/drain trench 228. The bottom thickness BTK_{(D)} of the dielectric film 240 is smaller or larger than half of the depth of the source/drain trench 228. Further, during the etch back process of the dielectric film 240, the dielectric film 240 may be etched through and divided into three portions with the side portions higher than the middle portion for a vertical distance (H_{DF}) measured between about 0.1 nm and about 114 nm. The gap width (W_{DF}) between two adjacent portions is between about 0.1 nm and 32 nm in some implementations. A void may be sealed under the source/drain feature 246 and laterally between the divided portions of the dielectric film 240. The source/drain feature 246 may also extend downward into the gap between the divided portions of the dielectric film 240 such that the bottom surface of the source/drain feature 246 may straddle the middle portion of the dielectric film 240.

Although not intended to be limiting, one or more embodiments of the present disclosure provide many benefits to a semiconductor device and the formation thereof. For example, embodiments of the present disclosure provide a transistor, particularly a p-type transistor, that includes a vertical stack of the channel members extending between two source/drain features and source/drain features extending below a top surface of the substrate directly under the channel members. The source/drain features are spaced apart from the substrate by a dielectric film and/or an undoped epitaxial layer. The dielectric film and/or the undoped epitaxial layer suppress substrate current leakage. By extending below the top surface of the substrate, the source/drain features have an enlarged volume which maintains a suitable amount of strain to the channel members.

In one exemplary aspect, the present disclosure is directed to a method. The method includes forming a stack over a substrate, the stack including a plurality of channel layers interleaved by a plurality of sacrificial layers, patterning the stack and a top portion of the substrate to form a fin-shape structure, the fin-shape structure including a channel region and a source/drain region, forming a dummy gate stack over the channel region of the fin-shape structure, depositing a gate spacer layer over the dummy gate stack, recessing the source/drain region to form a source/drain trench that exposes sidewalls of the plurality of channel layers and the plurality of sacrificial layers, selectively and partially recessing the plurality of sacrificial layers to form a plurality of inner spacer recesses, forming a plurality of inner spacer features in the plurality of inner spacer recesses, depositing a dielectric film in the source/drain trench, a top surface of the dielectric film being below a top surface of the substrate in the fin-shape structure, forming an epitaxial feature over the dielectric film, the epitaxial feature being in contact with the plurality of channel layers, a bottom surface of the epitaxial feature is below the top surface of the substrate in the fin-shape structure, after the forming of the epitaxial feature, removing the dummy gate stack, releasing the plurality of channel layers in the channel region as a plurality of channel members, and forming a gate structure wrapping around each of the plurality of channel members. In some embodiments, the method also includes prior to the depositing of the dielectric film, depositing a base epitaxial layer in the source/drain trench. In some embodiments, a dopant concentration of the epitaxial feature is greater than a dopant concentration of the base epitaxial layer. In some embodiments, the base epitaxial layer is dopant free. In some embodiments, the epitaxial feature is doped with boron (B). In some embodiments, the epitaxial feature and the base epitaxial layer comprise silicon germanium. In some embodiments, a germanium content of the epitaxial feature is greater than a germanium content of the base epitaxial layer. In some embodiments, a germanium content of the epitaxial feature is less than a germanium content of the base epitaxial layer. In some embodiments, the source/drain trench exposes a sidewall of the substrate, and the epitaxial feature is in physical contact with the sidewall of the substrate. In some embodiments, the depositing of the dielectric film includes depositing a dielectric material layer on a top surface of the base epitaxial layer and the sidewalls of the plurality of channel layers and the plurality of sacrificial layers, and etching back the dielectric material layer to remove the dielectric material layer from the sidewalls of the plurality of channel layers and the plurality of sacrificial layers. A portion of the dielectric material layer remains on the top surface of the base epitaxial layer as the dielectric film.

In another exemplary aspect, the present disclosure is directed to a method. The method includes forming a plurality of channel members disposed over a fin-shape substrate, forming a plurality of inner spacer features interleaving the plurality of channel members, depositing a dielectric material layer on sidewalls of the fin-shape substrate, the plurality of inner spacer features, and the plurality of channel members, etching back the dielectric material layer to form a dielectric film, a top surface of the dielectric film being below a top surface of the fin-shape substrate, depositing a first epitaxial layer over the dielectric film, the first epitaxial layer being in contact with the plurality of channel members, depositing a second epitaxial layer over the first epitaxial layer, the second epitaxial layer being in contact with the plurality of inner spacer features and the first epitaxial layer, and forming a gate structure wrapping around each of the plurality of channel members. The first epitaxial layer and the second epitaxial layer comprise silicon germanium. A germanium content of the second epitaxial layer is greater than a germanium content of the first epitaxial layer. In some embodiments, a bottom surface of the first epitaxial layer is below the top surface of the fin-shape substrate. In some embodiments, the first epitaxial layer is in physical with the dielectric film, and the first epitaxial layer separates the second epitaxial layer from the dielectric film. In some embodiments, each of the first epitaxial layer and the second epitaxial layer is in physical with the dielectric film. In some embodiments, the second epitaxial layer caps a void between the dielectric film and the second epitaxial layer. In some embodiments, the method also includes prior to the depositing of the dielectric material layer, depositing an undoped epitaxial layer in physical contact with the sidewall of the fin-shape substrate. In some embodiments, the dielectric film comprises a metal oxide or a metal nitride.

In yet another exemplary aspect, the present disclosure is directed to a semiconductor device. The semiconductor device includes a fin-shape base protruding from a substrate, a plurality of channel members disposed over a top surface of the fin-shape base, a plurality of inner spacer features interleaving the plurality of channel members, a gate structure wrapping around each of the plurality of channel members, a source/drain feature in contact with the plurality of channel members and the plurality of inner spacer features, a bottom surface of the source/drain feature being under the top surface of the fin-shape base, and a dielectric film directly under the source/drain feature, a top surface of the dielectric film being under the top surface of the fin-shape base. In some embodiments, the semiconductor device also includes an undoped epitaxial layer directly under the dielectric film and above the substrate. In some embodiments, the source/drain feature is in physical contact with a sidewall of the fin-shape base.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack over a substrate, the stack comprising a plurality of channel layers interleaved by a plurality of sacrificial layers;
patterning the stack and a top portion of the substrate to form a fin-shape structure, the fin-shape structure comprising a channel region and a source/drain region;
forming a dummy gate stack over the channel region of the fin-shape structure;
depositing a gate spacer layer over the dummy gate stack;
recessing the source/drain region to form a source/drain trench that exposes sidewalls of the plurality of channel layers and the plurality of sacrificial layers;
selectively and partially recessing the plurality of sacrificial layers to form a plurality of inner spacer recesses;
forming a plurality of inner spacer features in the plurality of inner spacer recesses;
depositing a dielectric film in the source/drain trench, a top surface of the dielectric film being below a top surface of the substrate in the fin-shape structure;
forming an epitaxial feature over the dielectric film, the epitaxial feature being in contact with the plurality of channel layers, a bottom surface of the epitaxial feature is below the top surface of the substrate in the fin-shape structure;
after the forming of the epitaxial feature, removing the dummy gate stack;
releasing the plurality of channel layers in the channel region as a plurality of channel members; and
forming a gate structure wrapping around each of the plurality of channel members.

2. The method of claim 1, further comprising:
prior to the depositing of the dielectric film, depositing a base epitaxial layer in the source/drain trench.

3. The method of claim 2, wherein a dopant concentration of the epitaxial feature is greater than a dopant concentration of the base epitaxial layer.

4. The method of claim 3, wherein the base epitaxial layer is dopant free.

5. The method of claim 3, wherein the epitaxial feature is doped with boron (B).

6. The method of claim 2, wherein the epitaxial feature and the base epitaxial layer comprise silicon germanium.

7. The method of claim 6, wherein a germanium content of the epitaxial feature is greater than a germanium content of the base epitaxial layer.

8. The method of claim 6, wherein a germanium content of the epitaxial feature is less than a germanium content of the base epitaxial layer.

9. The method of claim 1, wherein the source/drain trench exposes a sidewall of the substrate, and wherein the epitaxial feature is in physical contact with the sidewall of the substrate.

10. The method of claim 1, wherein the depositing of the dielectric film includes:
depositing a dielectric material layer on a top surface of the base epitaxial layer and the sidewalls of the plurality of channel layers and the plurality of sacrificial layers; and
etching back the dielectric material layer to remove the dielectric material layer from the sidewalls of the plurality of channel layers and the plurality of sacrificial layers, wherein a portion of the dielectric material layer remains on the top surface of the base epitaxial layer as the dielectric film.

11. A method, comprising:
forming a plurality of channel members disposed over a fin-shape substrate;
forming a plurality of inner spacer features interleaving the plurality of channel members;
depositing a dielectric material layer on sidewalls of the fin-shape substrate, the plurality of inner spacer features, and the plurality of channel members;
etching back the dielectric material layer to form a dielectric film, a top surface of the dielectric film being below a top surface of the fin-shape substrate;
depositing a first epitaxial layer over the dielectric film, the first epitaxial layer being in contact with the plurality of channel members;
depositing a second epitaxial layer over the first epitaxial layer, the second epitaxial layer being in contact with the plurality of inner spacer features and the first epitaxial layer; and
forming a gate structure wrapping around each of the plurality of channel members,
wherein the first epitaxial layer and the second epitaxial layer comprise silicon germanium,
wherein a germanium content of the second epitaxial layer is greater than a germanium content of the first epitaxial layer.

12. The method of claim 11, wherein a bottom surface of the first epitaxial layer is below the top surface of the fin-shape substrate.

13. The method of claim 11, wherein the first epitaxial layer is in physical with the dielectric film, and the first epitaxial layer separates the second epitaxial layer from the dielectric film.

14. The method of claim 11, wherein each of the first epitaxial layer and the second epitaxial layer is in physical with the dielectric film.

15. The method of claim 11, wherein the second epitaxial layer caps a void between the dielectric film and the second epitaxial layer.

16. The method of claim 11, further comprising:
prior to the depositing of the dielectric material layer, depositing an undoped epitaxial layer in physical contact with the sidewall of the fin-shape substrate.

17. The method of claim 11, wherein the dielectric film comprises a metal oxide or a metal nitride.

18. A semiconductor device, comprising:
a fin-shape base protruding from a substrate;
a plurality of channel members disposed over a top surface of the fin-shape base;
a plurality of inner spacer features interleaving the plurality of channel members;
a gate structure wrapping around each of the plurality of channel members;
a source/drain feature in contact with the plurality of channel members and the plurality of inner spacer features, a bottom surface of the source/drain feature being under the top surface of the fin-shape base; and
a dielectric film directly under the source/drain feature, a top surface of the dielectric film being under the top surface of the fin-shape base.

19. The semiconductor device of claim 18, further comprising:
an undoped epitaxial layer directly under the dielectric film and above the substrate.

20. The semiconductor device of claim 18, wherein the source/drain feature is in physical contact with a sidewall of the fin-shape base.
